(19) United States
(12) Patent Application Publication
(10) Pub. No.: US 2025/0172590 A1
(43) Pub. Date: May 29, 2025

(54) PROBE CARD FOR TESTING SEMICONDUCTOR DEVICE

(71) Applicant: LX SEMICON CO., LTD., Daejeon (KR)

(72) Inventors: Jin Hwan KIM, Daejeon (KR); Chan Mo KIM, Daejeon (KR)

(73) Assignee: LX SEMICON CO., LTD., Daejeon (KR)

(21) Appl. No.: 18/958,888

(22) Filed: Nov. 25, 2024

(30) Foreign Application Priority Data
Nov. 27, 2023 (KR) 10-2023-0166452

(51) Int. Cl. G01R 1/073

(52) U.S. Cl. CPC G01R 1/07342

(57) ABSTRACT

The present invention relates to a probe card mounted in a tester device for measuring the electrical characteristics of a semiconductor chip formed on a semiconductor substrate. The probe card for testing the electrical characteristics of a semiconductor device includes a plate-shaped support body, a circuit board located at an outer side of the support body, a first probe portion that is electrically connected to the circuit board and comes into contact with a first position of the semiconductor device, a second probe portion that is electrically connected to the circuit board and comes into contact with a second position of the semiconductor device, a first support portion supporting the first probe portion and having a first space portion at a central side, and a second support portion located on the first support portion, supporting the second probe portion, and having a second space portion in a central side.

### CROSS-REFERENCE TO RELATED APPLICATION

This application claims priority to and the benefit of Korean Patent Application No. 10-2023-0166452, filed on Nov. 27, 2023, the disclosure of which is incorporated herein by reference in its entirety.

### BACKGROUND

### 1. Field of the Invention

The present invention relates to a probe card mounted in a tester device for measuring the electrical characteristics of a semiconductor chip formed on a semiconductor substrate.

### 2. Discussion of Related Art

An electrical die sorting (EDS) process is an electrical characteristic inspection performed between a fabrication (FAB) process and a packaging process that has a final product form. Through the electrical characteristic inspection of semiconductor devices (for example, integrated circuit chips), it is possible to confirm whether individual semiconductor devices (chips) have reached a desired quality level.

Specifically, the electrical characteristic inspection checks whether each semiconductor device implemented on a wafer reaches a desired quality level. Specifically, through the electrical characteristic inspection, it is determined whether each semiconductor device implemented on the wafer passes or fails depending on whether each semiconductor device satisfies a desired electrical characteristic specification level or not. A specific mark is made (inked) on a failed chip. Since a chip determined to be defective in this way is excluded from subsequent processes, it is possible to increase manufacturing efficiency.

As such, the EDS process is a process required to increase the yield of semiconductors as a final test (packaging process performed on a passed chip). The yield of the semiconductors is calculated as a percentage of the number of prime good chips produced compared to the maximum number of chips designed on one wafer and is directly linked to the productivity of the semiconductors.

The EDS process can be performed by bringing a probe card connected to a testing device into contact with the wafer on which the semiconductor devices have been fabricated. Numerous fine pins (probe portions) provided on the probe card come into contact with pads of individual semiconductor devices fabricated on the wafer to send electricity, and defective chips can be identified through the signals.

FIG. 1 is a schematic cross-sectional view showing main portions of a typical probe card. FIG. 2 is a schematic cross-sectional view showing a state in which a probe portion of the typical probe card is in contact with a semiconductor device.

A typical probe card 1 may include a first probe portion 13 and a second probe portion 14 connected to a printed circuit board (not shown). The first probe portion 13 and the second probe portion 14 are supported by a single support portion 11. In this case, the first probe portion 13 and the second probe portion 14 may be supported on the support portion 11 by an adhesive portion 12 such as epoxy.

The probe card 1 including the first probe portion 13 and the second probe portion 14 may come into contact with a semiconductor device 2 such as an integrated circuit chip to perform the EDS. One semiconductor device 2 may be provided with an outer pad 22 and an inner pad 23. From the perspective of the semiconductor device 2, the inner pad 23 may be a pad located at a central side of a chip.

In order to perform the EDS of the semiconductor device 2, the first probe portion 13 may come into contact with the outer pad 22, and the second probe portion 14 may come into contact with the inner pad 23.

Referring to FIG. 2, the second probe portion 14 may come into contact with the inner pad 23 at a relatively long distance from the adhesive portion 12. In this case, the second probe portion 14 may have a large deviation (a) in an up-and-down movement of an end portion side that is bent. Accordingly, when coming into contact with the inner pad 23, a phenomenon in which an end portion of the second probe portion 14 is pushed inward (b) may occur.

As such, when a beam length corresponding to a length from an end portion of the support portion 11 to the bent portion of the second probe portion 14 becomes longer, the end portion (needle) of the second probe portion 14 may be pushed and the end portion (needle) of the second probe portion 14 may move up and down at the bent portion, thereby causing a deviation.

Therefore, a solution to these problems is required.

### SUMMARY

One embodiment of the present invention is directed to providing a probe card for testing a semiconductor device, which, when a probe portion of the probe card comes into contact with an inner pad of the semiconductor device, enables the probe portion to stably come into contact with the inner pad without being pushed from the pad of the semiconductor device.

In addition, the present invention is directed to providing a probe card for testing a semiconductor device, which can reduce a beam length corresponding to a length from an end portion of a support portion of the probe card to a bent portion of a probe portion.

In addition, the present invention is directed to providing a probe card for testing a semiconductor device, which enables stable and simultaneous contact with a plurality of semiconductor devices to test the semiconductor devices.

As a first aspect of the present invention for achieving the object described above, a probe card for testing the electrical characteristics of a semiconductor device includes a support body, a circuit board located at an outer side of the support body, a first probe portion that is electrically connected to the circuit board and comes into contact with a first position of the semiconductor device, a second probe portion that is electrically connected to the circuit board and comes into contact with a second position of the semiconductor device, a first support portion supporting the first probe portion and having a first space portion that exposes the first probe portion at a central side, and a second support portion located on the first support portion, supporting the second probe portion, and having a second space portion that exposes the second probe portion coaxially with the central side.

In an exemplary embodiment, the first support portion and the second support portion may have the same inclined surface with respect to the plate shape of the support body.

In an exemplary embodiment, the second support portion may be located to further extend toward the central side than the first support portion with respect to the first space portion.

In an exemplary embodiment, the first support portion may be located to overlap the second support portion.

In an exemplary embodiment, the first support portion and the second support portion may be provided in ring shapes made of a ceramic.

In an exemplary embodiment, the second probe portion may be located inward from the first probe portion with respect to the first space portion or the second space portion.

In an exemplary embodiment, the first probe portion may be located to extend inward by a first length from an end portion of the first support portion

In an exemplary embodiment, the second probe portion may be located to extend inward by a second length from an end portion of the second support portion.

In an exemplary embodiment, the first space portion may be located coaxially with the second space portion.

In an exemplary embodiment, a size of the first space portion may be larger than a size of the second space portion.

In an exemplary embodiment, the first space portion and the second space portion may be provided so that at least two or more are disposed in parallel.

As a second aspect of the present invention for achieving the object described above, a probe card for testing the electrical characteristics of a semiconductor device includes a support body, a circuit board located at an outer side of the support body, a first support portion supported by the support body and having a first space portion in a central side, a second support portion located on the first support portion and having a second space portion at a central side, a first probe portion electrically connected to the circuit board and supported by the first support portion, and a second probe portion electrically connected to the circuit board and supported by the second support portion.

In an exemplary embodiment, the first probe portion may come into contact with a first position of the semiconductor device, and the second probe portion may come into contact with a second position of the semiconductor device.

In an exemplary embodiment, the second position may be located inward from the first position with respect to the first space portion or the second space portion.

As a third aspect of the present invention for achieving the object described above, a probe card for testing the electrical characteristics of a semiconductor device includes a first probe portion that comes into contact with a first position of a semiconductor device, a second probe portion that comes into contact with a second position located at an inner side of the first position of the semiconductor device, a first support portion that supports the first probe portion and has a first space portion at a central side, and a second support portion that is located on the first support portion to support the second probe portion and has a second space portion located coaxially with the first space portion at a central side, wherein the first probe portion may be located to extend inward by a first length with respect to the first space portion, and the second probe portion may be located to extend inward by a second length with respect to the second space portion.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic cross-sectional view showing main portions of a typical probe card;

FIG. 2 is a schematic cross-sectional view showing a state in which a probe portion of the typical probe card is in contact with a semiconductor device;

FIG. 3 is a schematic plan view showing a probe card according to one embodiment of the present invention;

FIG. 4 is a schematic cross-sectional view showing the probe card according to one embodiment of the present invention;

FIG. 5 is a schematic cross-sectional view showing a state in which the probe card is brought into contact with a semiconductor device according to one embodiment of the present invention;

FIG. 6 is an exploded perspective view of the probe card according to one embodiment of the present invention as viewed from a first direction;

FIG. 7 is an exploded perspective view of the probe card according to one embodiment of the present invention as viewed from a second direction;

FIG. 8 is a perspective view of the probe card according to one embodiment of the present invention as viewed from the second direction;

FIG. 9 is an exploded perspective view of a probe card according to another embodiment of the present invention as viewed from the first direction;

FIG. 10 is an exploded perspective view of the probe card according to another embodiment of the present invention as viewed from the second direction;

FIG. 11 is a perspective view of the probe card according to another embodiment of the present invention as viewed from the second direction;

FIGS. 12 to 14 are plan views showing a state in which a first probe portion and a second probe portion are coupled in the probe card according to another embodiment of the present invention;

FIG. 15 is a perspective view showing a state in which the first probe portion and the second probe portion are coupled in the probe card according to another embodiment of the present invention; and

FIGS. 16 and 17 are conceptual diagrams showing inspection methods according to one embodiment and another embodiment of the present invention.

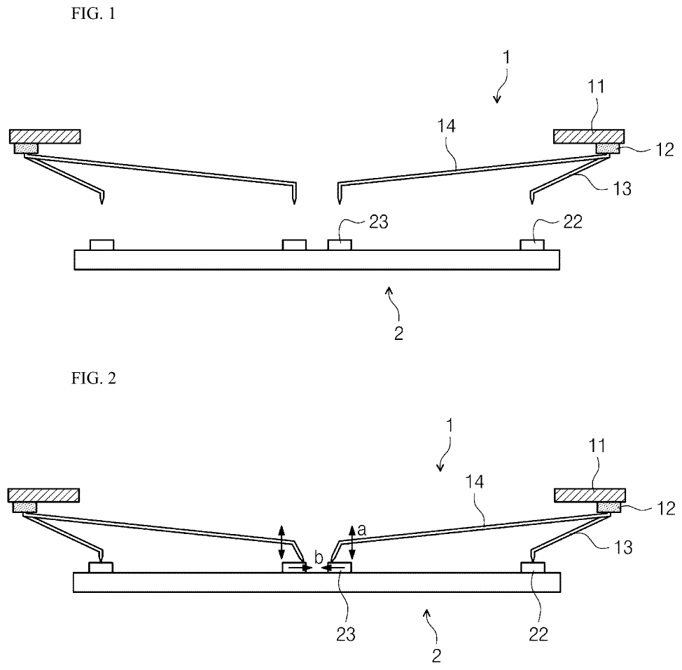

### DETAILED DESCRIPTION OF EXEMPLARY EMBODIMENTS

Hereinafter, embodiments disclosed in the present specification will be described in detail with reference to the accompanying drawings, and the same or similar components are denoted by the same reference numerals regardless of the drawing symbols, and overlapping descriptions thereof will be omitted. The suffixes “module” and “unit” for components used in the following description are given or used interchangeably in consideration of ease of preparing the specification and do not have distinct meanings or roles in themselves.

In addition, in describing the embodiments disclosed in the present specification, when it is judged that a detailed description of related known technology may obscure the gist of the embodiments disclosed in the present specification, the detailed description thereof will be omitted.

In addition, it should be noted that the accompanying drawings are only intended to facilitate easy understanding of the embodiments disclosed in the present specification and that the technical ideas disclosed in the present specification should not be construed as being limited by the accompanying drawings.

Furthermore, although each drawing is described for convenience of explanation, it is within the scope of the present invention that those skilled in the art may implement other embodiment by combining at least two or more drawings.

In addition, when an element such as a layer, a region, or a substrate is mentioned as being present “on” another element, it will be understood that it may be directly on the other element, or that am intermediate element may be present between them.

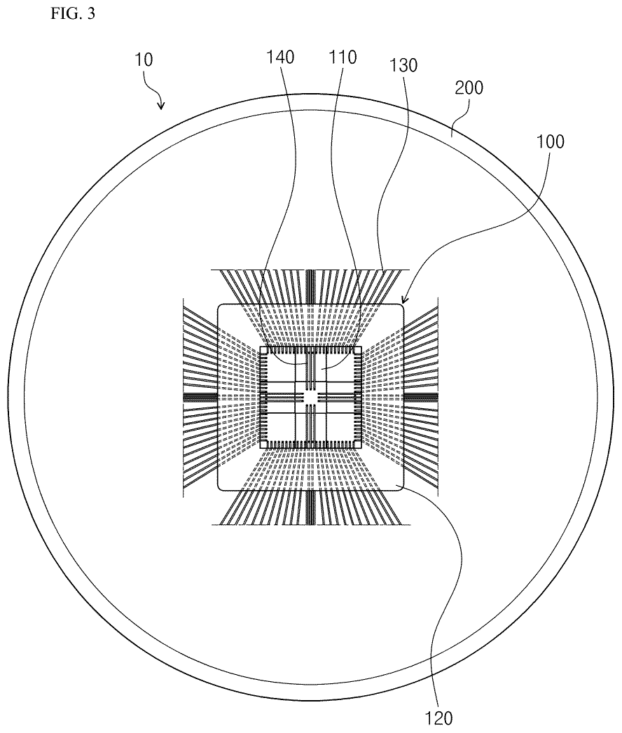

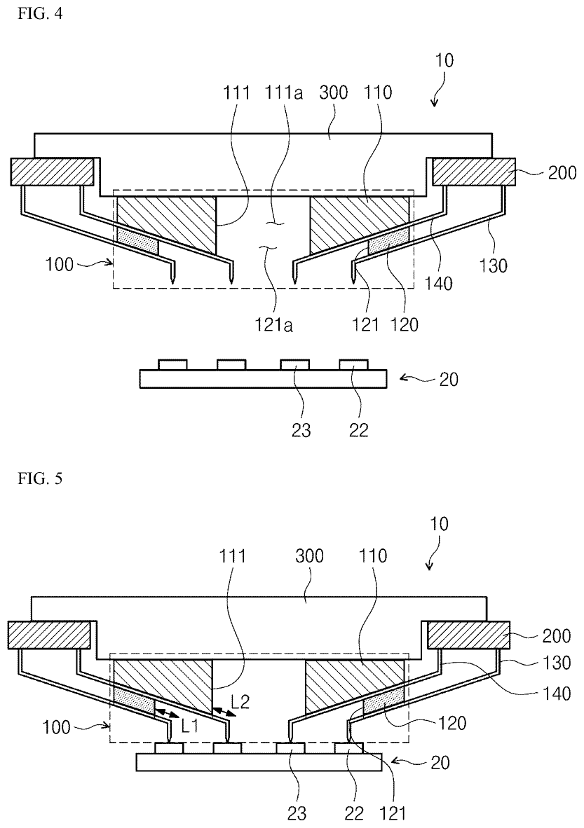

FIG. 3 is a schematic plan view showing a probe card according to one embodiment of the present invention. FIG. 4 is a schematic cross-sectional view showing the probe card according to one embodiment of the present invention.

Referring to FIGS. 3 and 4, a probe card 10 according to one embodiment of the present invention may test the electrical characteristics of a semiconductor device 20. For example, an electrical die sorting (EDS) process may be performed using the probe card 10.

Here, the semiconductor device 20 is, for example, an integrated circuit chip (IC chip), and FIG. 4 schematically shows a unit semiconductor device 20 implemented on a wafer. The semiconductor device 20 may include a first pad 22 located at a first position and a second pad 23 located at a second position. In one example, the unit semiconductor device 20 may have a first pad 22 located at an outer side and a second pad 23 located at an inner side of the first pad 22.

The probe card 10 may include a plate-shaped support body 300, a circuit board 200 located at an outer side of the support body 300, and an inner core structure 100 including support portions 110 and 120 supporting probe portions 130 and 140 electrically connected to the circuit board 200.

Although not shown separately, the circuit board 200 is, for example, a printed circuit board (PCB) and may be electrically connected to a testing device that can test the semiconductor device 20. Details on this are omitted.

In the probe card 10, the support body 300 may be formed in a plate shape. The circuit board 200 may be located at the outer side of the support body 300. For example, the circuit board 200 may be located at the outer side of the support body 300 to surround the outer side of the support body 300. As an exemplary embodiment, the circuit board 200 may be provided in a circular shape (donut shape). In FIG. 4, the size of the circuit board 200 is schematically shown as being reduced compared to FIG. 2.

The probe card 10 may include a first probe portion 130 that is electrically connected to circuit board 200 and comes into contact with the first position of the semiconductor device 20 and a second probe portion 140 that is electrically connected to the circuit board 200 and comes into contact with the second position of the semiconductor device 20. For example, the first probe portion 130 may come into contact with an outer pad (a first pad) 22 of the semiconductor device 20, and the second probe portion 140 may come into contact with an inner pad (a second pad) 23 of the semiconductor device 20.

In addition, the probe card 10 may include a first support portion 120 that supports the first probe portion 130 and has a first space portion 121a in a central side and a second support portion 110 that is located on the first support portion 120, supports the second probe portion 140, and has a second space portion 111a in a central side.

A structure including the first probe portion 130, the second probe portion 140, and the first support portion 120 and the second support portion 110 that respectively support the first probe portion 130 and the second probe portion 140 may be referred to as the core structure 100. Here, reference numerals for the first support portion 120 and the second support portion 110 are set for convenience according to a connection distance from the support body 300.

Referring to FIG. 4, for example, the first support portion 120 and the second support portion 110 may have the same inclined surface with respect to the plate-shaped support body 300. Meanwhile, as another example, the first support portion 120 and the second support portion 110 may have different inclined surfaces with respect to the plate-shaped support body 300.

In an exemplary embodiment, the second support portion 110 may be located to extend further inward than the first support portion 120 with respect to the first space portion 121a. For example, since the second support portion 110 supports the second probe portion 140 that comes into contact with the second pad 23 located at the inner side of the semiconductor device 20, the second support portion 110 may be located to extend further inward than the first support portion 120 with respect to the central side of the probe card 10. Accordingly, an unnecessary external force is not applied to the second probe portion 140 that comes into contact with the second pad 23 located at the inner side of the semiconductor device 20, and the second probe portion 140 can be stably supported by the second support portion 110. This will be described in more detail below.

Referring to FIG. 4, the first support portion 120 may be located to overlap the second support portion 110. One side surface of the second support portion 110 may be supported by the support body 300, and the other side surface of the second support portion 110 may support the second probe portion 140. At the same time, the first support portion 120 may be located close to or in contact with the other side surface of the second support portion 110. At least a partial region of the second support portion 110 may overlap the first support portion 120. For example, the second support portion 110 may have a larger area, and the first support portion 120 may be located on a partial area of the larger area.

FIG. 5 is a schematic cross-sectional view showing a state in which the probe card is brought into contact with a semiconductor device according to one embodiment of the present invention.

Referring to FIG. 5, a state in which the probe card 10 is brought into contact with the semiconductor device 20 to inspect the semiconductor device 20 using the probe card 10 is shown.

Specifically, a state in which an end portion of the first probe portion 130 is brought into contact with the outer pad (the first pad) 22 of the semiconductor device 20 and an end portion of the second probe portion 140 is brought into contact with the inner pad (the second pad) 23 of the semiconductor device 20 is shown.

In this case, since an end portion side of the first probe portion 130 is supported by the first support portion 120, the first probe portion 130 can stably come into contact with the first pad 22. In addition, since an end portion side of the second probe portion 140 is supported by the second support portion 110, the second probe portion 140 can stably come into contact with the second pad 23.

The first probe portion 130 may be located to extend inward by a first length L1 from an end portion 121 of the first support portion 120. That is, the first probe portion 130 may be located to be exposed on the first space portion 121a by being exposed from the end portion 121 of the first support portion 120. In addition, the second probe portion 140 may be located to extend inward by a second length L2 from an end portion 111 of the second support portion 110. That is, the second probe portion 140 may be located to be exposed on the second space portion 111a by being exposed from the end portion 111 of the second support portion 110. As such, a portion extended from the end portion 111 or 121 may be referred to as a beam length.

According to the embodiment of the present invention, the beam lengths L1 and L2 may be configured to be shortened so that the first support portion 120 and the second support portion 110 may stably support the end portion sides of the first probe portion 130 and the second probe portion 140, respectively. As such, when the beam length is shortened, the second probe portion 140 can stably come into contact with the inner pad (the second pad) 23 of the semiconductor device 20 without the end portion of the second probe portion 140 being pushed.

In particular, according to the embodiment of the present invention, the second support portion 110 forms an inclined surface separately to stably support the end portion side of the second probe portion 140. When there is no the second support portion 110, the second probe portion 140 is supported by the first support portion 120 to come into contact with the inner pad 23, but, according to the embodiment of the present invention, since the second probe portion 140 is supported by the second support portion 110, the beam length can be shortened, thereby stably supporting the second probe portion 140.

Although not shown separately, the first probe portion 130 may be firmly supported by being attached to the first support portion 120 using an adhesive such as epoxy. In addition, the second probe portion 140 may be firmly supported by being attached to the second support portion 110 using an adhesive such as epoxy.

In an exemplary embodiment, the first support portion 120 and the second support portion 110 may be provided in ring shapes made of a ceramic. For example, the first support portion 120 may be made of a ring-shaped ceramic having the first space portion 121a in the central side. In addition, the second support portion 110 may be made of a ring-shaped ceramic having the second space portion 111a in the central side.

The first space portion 121a may be located coaxially with the second space portion 111a. For example, the first space portion 121a and the second space portion 111a may be provided to be coupled to each other coaxially.

In this case, referring to FIGS. 4 and 5, a size of the first space portion 121a may be larger than a size of the second space portion 111a. This may be because the second probe portion 140 that comes into contact into the second pad 23 located on the inside is located further inward than the second space portion 111a.

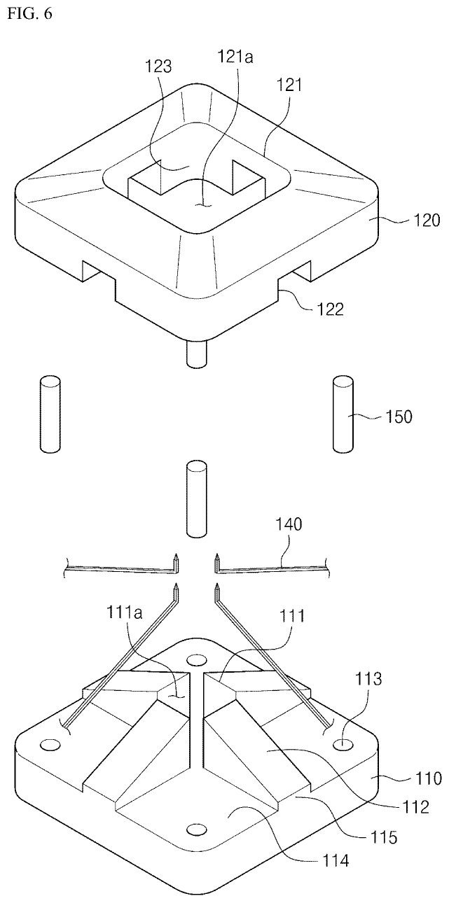

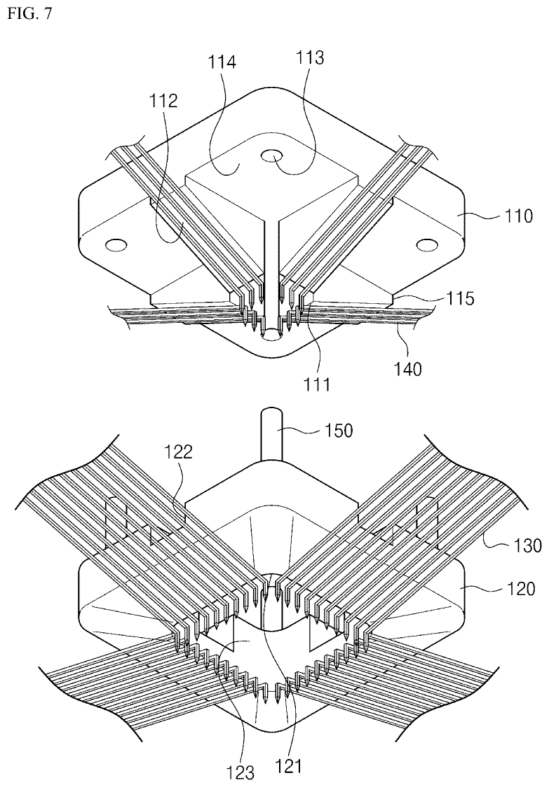

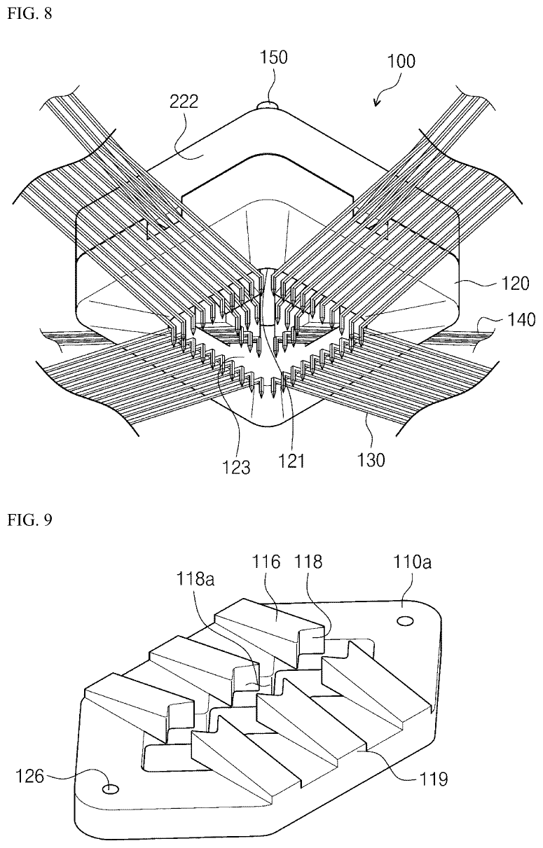

FIG. 6 is an exploded perspective view of the probe card according to one embodiment of the present invention as viewed from a first direction. FIG. 7 is an exploded perspective view of the probe card according to one embodiment of the present invention as viewed from a second direction. FIG. 8 is a perspective view of the probe card according to one embodiment of the present invention as viewed from the second direction.

Referring to FIG. 6, as an exemplary embodiment, specific shapes of the first support portion 120 and the second support portion 110 are shown. Here, the first support portion 120 may be coupled onto the second support portion 110. The second support portion 110 and the first support portion 120 may be coupled by a pin 150.

In the second support portion 110, inclined surfaces 112 protruding from a base surface 114 are each formed at a central side 115 of each side of the end portions 111 and meet at a central side to form the second space portion 111a. A pinhole 113 to which the pin 150 is coupled may be located on the base surface 114. The second probe portion 140 may be supported on the inclined surface 112. As mentioned above, the second probe portion 140 may be supported on the inclined surface 112 using an adhesive such as epoxy.

In the first support portion 120 coupled to the second support portion 110, a coupling hole 122 to which the second probe portion 140 is coupled may be located at a position corresponding to the inclined surface 112 of the second support portion 110. A support surface 123 may be formed to extend inward in the first space portion 121a of the first support portion 120.

As such, since the coupling hole 122 to which the second probe portion 140 is coupled is coupled to the central side 115 of each edge of the end portions, the first support portion 120 and the second support portion 110 may be firmly coupled.

Referring to FIG. 7, it can be seen that an outer surface of the first support portion 120 itself forms an inclined surface to support the first probe portion 130. The end portion side of the first probe portion 130 may be provided to protrude inward from the first space portion 121a. That is, the end portion side of the first probe portion 130 may be provided to protrude inward from the end portion 121 of the first support portion 120.

In addition, as described above, a state in which the second probe portion 140 is supported by the inclined surface 112 of the second support portion 110 is shown. The second probe portion 140 may be connected to the circuit board 200 by passing through the coupling hole 122 and extending in the opposite direction to a protruding direction.

When the first support portion 120 and the second support portion 110 are coupled, and the first probe portion 130 and the second probe portion 140 are coupled to the first support portion 120 and the second support portion 110, respectively, the state shown in FIG. 8 may be formed.

In the above state, the first probe portion 130 and the second probe portion 140 can stably come into contact with the first pad 22 and the second pad 23 of the semiconductor device 20 without the end portions being pushed to test the electrical characteristics of the semiconductor device 20.

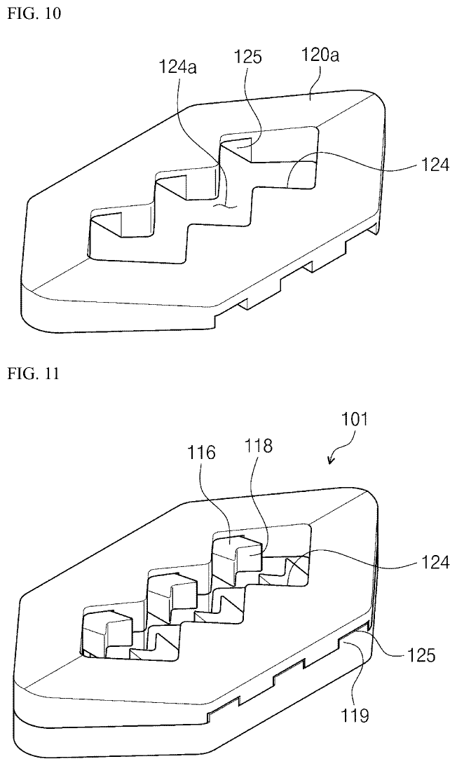

FIG. 9 is an exploded perspective view of a probe card according to another embodiment of the present invention as viewed from the first direction. FIG. 10 is an exploded perspective view of the probe card according to another embodiment of the present invention as viewed from the second direction. FIG. 11 is a perspective view of the probe card according to another embodiment of the present invention as viewed from the second direction.

FIGS. 9 to 11 show a core structure 101 of the probe card according to another embodiment of the present invention. The core structure 101 according to this embodiment may be provided with a plurality of first space portions 124a and second space portions 118a to which the first probe portion 130 and the second probe portion 140 may be coupled. Accordingly, a plurality of semiconductor devices 20 can be simultaneously inspected according to groups of a plurality of first probe portions 130 and second probe portions 140 that are coupled to the plurality of first space portions 124a and second space portions 118a.

For example, referring to FIGS. 9 to 11, three sets of the first probe portion 130 and the second probe portion 140 that are described above are provided in order to simultaneously come into contact with three semiconductor devices 20 and simultaneously inspect the three semiconductor devices 20. Here, a state in which the three sets of the first probe portion 130 and the second probe portion 140 are provided is exemplarily shown, but it goes without saying that a different number of the first probe portions 130 and the second probe portions 140 can be provided as a set.

Referring to FIG. 9, three sets of inclined surfaces 116 are formed on a second support portion 110a. In addition, an end portion 118 of each inclined surface 116 is formed in a V-shape so that when the end portions 118 of two inclined surfaces 116 meet each other, the second space portion 118a having a square shape may be formed.

Meanwhile, referring to FIG. 10, it can be seen that three first space portions 124a are formed in parallel in a first support portion 120a. A coupling hole 125 (see FIG. 10) to which the inclined surface 116 of the second support portion 110a is coupled may be provided on one side of the first space portion 124a.

Referring to FIG. 11, the second support portion 110a and the first support portion 120a are coupled to form a core structure 101 capable of simultaneously inspecting three semiconductor devices 20.

In the second support portion 110a, inclined surfaces 116 each protruding from a central side 119 of each side of the end portions 118 are formed and meet at a central side to form the second space portion 118a. The second probe portion 140 may be supported on the inclined surface 116. As mentioned above, the second probe portion 140 may be supported on the inclined surface 116 using an adhesive such as epoxy.

In the first support portion 120a coupled to the second support portion 110a, the coupling hole 125 to which the second probe portion 140 is coupled may be located at a position corresponding to the inclined surface 116 of the second support portion 110a.

As such, since the coupling hole 125 to which the second probe portion 140 is coupled is coupled to the central side 119 of each edge of the end portions, the first support portion 120 and the second support portion 110 may be firmly coupled by coupling of a stepped shape. In this case, the first support portion 120a and the second support portion 110a may be coupled by a pin (not shown) and a pinhole 126 similarly to the case of the first embodiment. That is, the first support portion 120a and the second support portion 110a may be coupled to each other by a separate pin. Referring to FIG. 9, the pinhole 126 formed in the second support portion 110a is shown. Although not shown separately, a pinhole to which a pin is coupled may also be formed in the second support portion 110a.

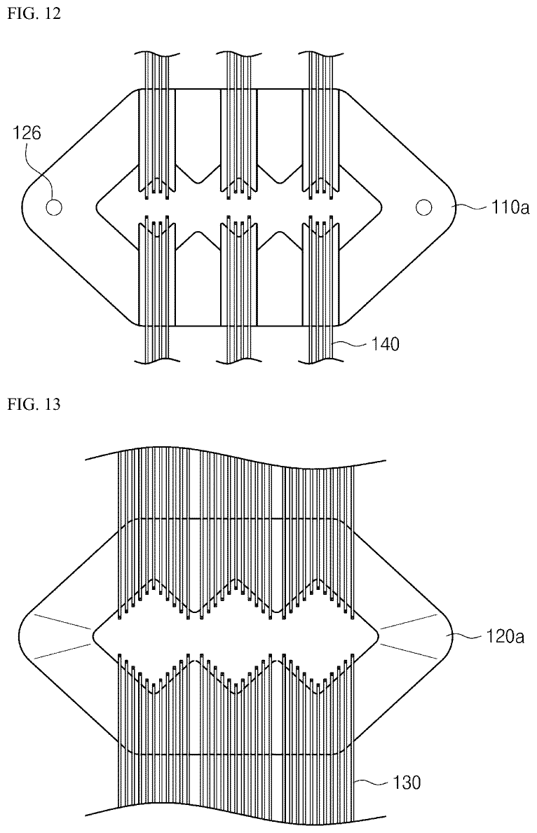

FIGS. 12 to 14 are plan views showing a state in which the first probe portion and the second probe portion are coupled in the probe card according to another embodiment of the present invention.

FIG. 12 exemplarily shows a state in which the second probe portion 140 is coupled to the second support portion 110a. FIG. 13 exemplarily shows a state in which the first probe portion 130 is coupled to the first support portion 120a.

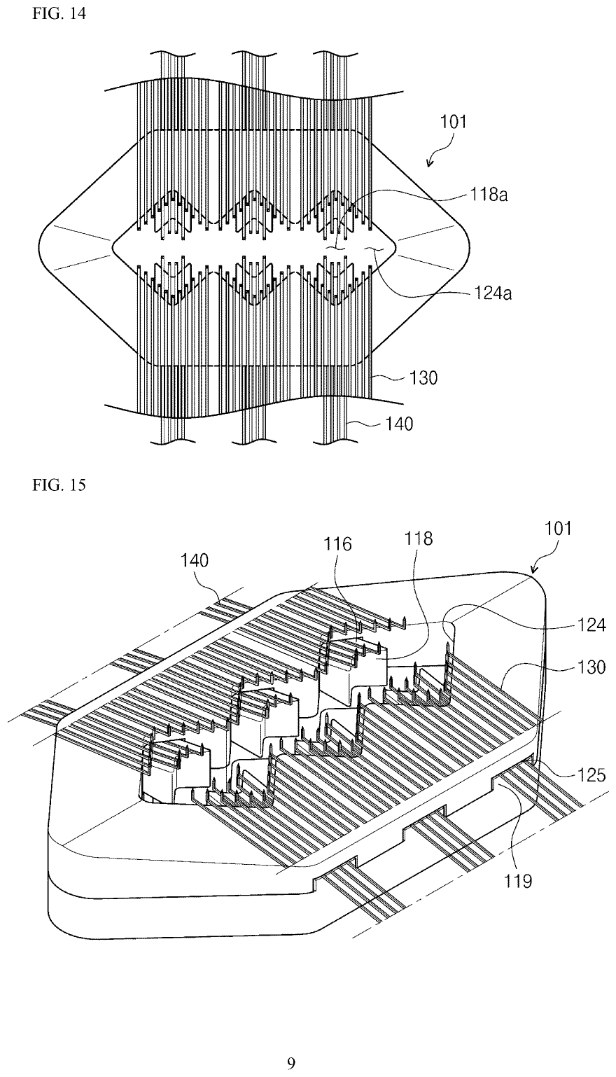

FIG. 14 exemplarily shows a core structure 101 formed by the coupling of the first support portion 120a and the second support portion 110a and the coupling of the first probe portion 130 and the second probe portion 140.

FIG. 15 is a perspective view showing a state in which the first probe portion and the second probe portion are coupled in the probe card according to another embodiment of the present invention.

Referring to FIG. 15, the core structure 101 formed by the coupling of the first support portion 120a and the second support portion 110a and the coupling of the first probe portion 130 and the second probe portion 140 is shown in more detail.

The first probe portion 130 may be supported by an outer surface of the first support portion 120a. The first space portion 124a is formed in the first support portion 120a, and the first probe portion 130 extends to an inner side of the first space portion 124a so that a probe may be positioned.

The second probe portion 140 may be supported by the inclined surface 116 of the second support portion 110a. The end portion 118 of the inclined surface 116 forms the second space portion 118a, and a probe of the second probe portion 140 may be located at an inner side of the second space portion 118a. In addition, an inner space of the end portion 124 of the first support portion 120a forms the first space portion 124a so that the probe of the first probe portion 130 may be positioned.

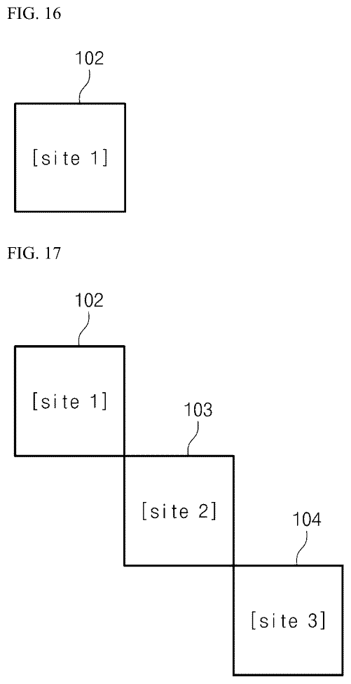

FIGS. 16 and 17 are conceptual diagrams showing inspection methods according to one embodiment and another embodiment of the present invention.

Referring to FIG. 16, the probe card 10 includes one inspection region 102 (site 1) as in one embodiment of the present invention described above and may inspect a unit semiconductor device using the one inspection region 102.

Meanwhile, referring to FIG. 17, the probe card 10 includes three inspection regions 102, 103, and 104 (site 1, site 2, and site 3) as in another embodiment of the present invention described above and may inspect three unit semiconductor devices using the three inspection regions 102, 103, and 104.

As described above, according to the embodiments of the present invention, by forming a ring-shaped ceramic support portion with two axes, the beam length of the probe portion located at the inner side thereof can be minimized.

As such, since the beam length is shortened, when the probe portion comes into contact with the inner (the central side) pad of the semiconductor device, the probe portion can stably come into contact with the inner pad without the end portion of the probe portion being pushed.

Therefore, it is possible to test integrated circuits (ICs) having pads (island pads) at a central side (inner portion) of the semiconductor device. In addition, there is an advantage in that restrictions related to a pad layout can be reduced during chip design.

According to exemplary embodiments of the present invention, the following effects are achieved.

First, according to one embodiment of the present invention, when a probe portion of a probe card comes into contact with an inner pad of a semiconductor device, the probe portion can stably come into contact with the inner pad without being pushed from the pad of the semiconductor device.

In addition, a beam length corresponding to a length from an end portion of a support portion of the probe card to a bent portion of the probe portion can be reduced.

In addition, it is possible to come into stable and simultaneous contact with a plurality of semiconductor devices and test the semiconductor devices.

Therefore, it is possible to test integrated circuits (ICs) having pads (island pads) at a central side (inner portion) of the semiconductor device. In addition, there is an advantage in that restrictions related to a pad layout can be reduced during chip design.

Furthermore, according to another embodiment of the present invention, there are additional technical effects not mentioned herein. Those skilled in the art may understand the additional technical effects through the specification and the accompanying drawings.

The above description is merely an exemplary description of the technical spirit of the present invention, and those skilled in the art to which the present invention pertains will be able to modify and change the present disclosure in various ways without departing from the essential characteristics of the present invention.

Therefore, the embodiments disclosed in the present invention are not intended to limit the technical spirit of the present invention, but to describe it, and the scope of the technical spirit of the present invention is not limited by these embodiments.

The scope of the present invention should be construed according to the appended claims, and all technical ideas within the equivalent range should be construed as being included in the scope of the present invention.

What is claimed is:

1. A probe card for testing electrical characteristics of a semiconductor device, comprising:
a support body;
a circuit board located at an outer side of the support body;
a first probe portion that is electrically connected to the circuit board and comes into contact with a first position of the semiconductor device;
a second probe portion that is electrically connected to the circuit board and comes into contact with a second position of the semiconductor device;
a first support portion supporting the first probe portion and having a first space portion that exposes the first probe portion at a central side; and
a second support portion located on the first support portion, supporting the second probe portion, and having a second space portion that exposes the second probe portion coaxially with the central side.

2. The probe card of claim 1, wherein the second support portion is located to further extend toward the central side than the first support portion with respect to the first space portion.

3. The probe card of claim 1, wherein the first support portion is located to overlap the second support portion.

4. The probe card of claim 1, wherein one side surface of the second support portion is supported by the support body, and the other side surface of the second support portion supports the second probe portion.

5. The probe card of claim 1, wherein the first support portion and the second support portion are provided in ring shapes made of a ceramic.

6. The probe card of claim 1, wherein the second probe portion is located inward from the first probe portion with respect to the first space portion or the second space portion.

7. The probe card of claim 1, wherein the first probe portion is located to extend inward by a first length from an end portion of the first support portion.

8. The probe card of claim 1, wherein the second probe portion is located to extend inward by a second length from an end portion of the second support portion.

9. The probe card of claim 1, wherein a size of the second space portion is smaller than a size of the first space portion.

10. The probe card of claim 1, wherein the first space portion and the second space portion are provided so that at least two or more are disposed in parallel.

11. A probe card for testing electrical characteristics of a semiconductor device, comprising:
a support body;
a circuit board located at an outer side of the support body;
a first support portion supported by the support body and having a first space portion at a central side;
a second support portion located on the first support portion and having a second space portion at a central side;
a first probe portion electrically connected to the circuit board and supported by the first support portion; and
a second probe portion electrically connected to the circuit board and supported by the second support portion.

12. The probe card of claim 11, wherein the second support portion is located to further extend toward the central side than the first support portion with respect to the first space portion.

13. The probe card of claim 11, wherein the first support portion is located to overlap the second support portion.

14. The probe card of claim 11, wherein one side surface of the second support portion is supported by the support body, and the other side surface of the second support portion supports the second probe portion.

15. The probe card of claim 11, wherein the first support portion and the second support portion are provided in ring shapes made of a ceramic.

16. The probe card of claim 11, wherein the second probe portion is located inward from the first probe portion with respect to the first space portion or the second space portion.

17. The probe card of claim 11, wherein the first probe portion is located to extend inward by a first length from an end portion of the first support portion.

18. The probe card of claim 11, wherein the second probe portion is located to extend inward by a second length from an end portion of the second support portion.

19. The probe card of claim 11, wherein a size of the second space portion is smaller than a size of the first space portion.

20. The probe card of claim 11, wherein the first space portion and the second space portion are provided so that at least two or more are disposed in parallel.
